(19) United States
(12) Patent Application Publication
(10) Pub. No.: US 2025/0279645 A1
(43) Pub. Date: Sep. 4, 2025

(54) INTEGRATED SOLID-STATE CIRCUIT BREAKER WITH SUPERCONDUCTING FAULT CURRENT LIMITER

(71) Applicants: Drexel University, Philadelphia, PA (US); University of Nebraska, Lincoln, NE (US)

(72) Inventors: Fei Lu, Wynnewood, PA (US); Hua Zhang, Philadelphia, PA (US); Reza Kheirollahi, Philadelphia, PA (US); Shuyan Zhao, Philadelphia, PA (US); Jun Wang, Lincoln, NE (US); Ekaterina Muravleva, Lincoln, NE (US); Md Mohaiminul Haque, Lincoln, NE (US)

(73) Assignees: Drexel University, Philadelphia, PA (US); University of Nebraska, Lincoln, NE (US)

(21) Appl. No.: 18/854,582

(22) PCT Filed: Apr. 5, 2023
(86) PCT No.: PCT/US23/65346

§ 371 Date: Oct. 7, 2024

Related U.S. Application Data
(60) Provisional application No. 63/327,548, filed on Apr. 5, 2022.

(51) Int. Cl. H02H 9/02; H02H 3/087

(52) U.S. Cl. CPC H02H 9/023; H02H 3/087; H02H 9/025

(57) ABSTRACT

A superconducting solid-state circuit breaker (S³CB) may be used in direct current (DC) power system applications. The proposed protective S³CB has two main protective functions. First, it slows down a rising rate of fault currents by using superconductors. A new quench resistor accelerator is proposed to fasten superconductors' response time to solve the low inertia of DC power systems. In addition, a quench protection branch is used to protect the superconductors from localized hotspots during current limiting processes. Second, the proposed S³CB includes an ultrafast solid-state circuit breaker (SSCB) which isolates faulty sections or disconnect loads within microseconds.

### RELATED APPLICATION(S)

This application claims priority under 35 U.S.C. § 119 (e) of the co-pending U.S. Provisional Patent Application Ser. No. 63/327,548, filed Apr. 5, 2022, and is a National Phase application of PCT/US23/65346 filed Apr. 5, 2023, both of which are hereby incorporated by reference in their entirety.

### STATEMENT REGARDING GOVERNMENT SUPPORT

This invention was made with government support under Contract No. DE-AR0001114 awarded by the ARPA-E. The government has certain rights in the invention.

### BACKGROUND OF THE INVENTION

### 1. Background and Related Work

Direct current (DC) power systems have been under noteworthy progress during recent decades, especially in medium-voltage (MV) to high-voltage (HV) applications. Some advantages of DC power systems, when compared with their alternative current (AC) counterparts, include presentation of higher efficiency in the same voltage level, elimination of the need for frequency synchronization and reactive power compensation, ease of renewable integration, and reduction in the number of power conversation stages. In addition, the applications of high-voltage direct current (HVDC) in interconnections of AC power systems and off-shore power transmissions indicate the importance of DC power systems.

However, developing DC power systems has some technical challenges. For instance, these include challenges related to DC circuit breakers (DCCBs) technology development, low thermal capability of semiconductors, power converters development, voltage-source-converter (VSC) and modular multilevel converter (MMC) development, and no clear standards for DC power systems, when developing DC power systems. The technical challenges with developing DCCBs include, but are not limited to, 1) no zero-crossing point in DC currents, and 2) low inertia of DC power systems, especially within distribution networks. Further, among DCCBs, solid-state circuit breakers (SSCBs) present faster response time, when compared to circuit breakers of other types. Further, SSCBs are modular, which makes them highly beneficial for future development of DC power systems.

SSCBs are considered as a promising solution worldwide, for newly established DC power systems. Further, introducing wide bandgap (WBG) semiconductors has accelerated the progress in the development of SSCBs due to the extended electrical ratings, which brings compactness, and the reduced on-state resistance which leads to high efficiency. In addition, an ultrafast reaction time interval within microsecond range is achieved, which is highly significant in protecting low inertia DC power systems. However, an SSCB acts as a switch in isolating a part of DC power systems, and has no flexibility in limiting fault currents or extending the ride-through capability of electrical networks.

Usage of fault current limiters helps in increasing the inertia of DC power systems and reducing the peak fault currents imposed on protective devices. Further, putting an inductor in series with transmission lines can slow down the rate of rise of fault currents during a short circuit, which brings a safe time margin for DCCBs having slow operations. In addition to power losses, line inductors impose energy dissipation on faulty sections and reduce the effectiveness of ultrafast SSCBs. The stored inductive energy of a line inductor needs to be dissipated by energy absorbing elements. Further, the stored inductive energy increases an amount of fault currents after isolation, which may cause safety issues in the electrical networks. In the recent times, superconductors have been under full considerations for developing current limiting functions in DC power systems. Although there are limitations in practice, superconductors overcome the problems accompanied by line inductors such as power losses and stored inductive energy. Superconductors present zero resistance (while keeping in a coolant such as liquid nitrogen) if they operate below their associated critical currents, temperature, and magnetic field levels. When placed in DC electrical circuits, superconductors show resistance when a DC current exceeds a threshold, indicating that superconductors can autonomously react to current faults and limit the fault currents in case of short circuits in DC electrical circuits. Also, connecting superconducting fault current limiter (SFCL) coils in series/parallel in electric circuits obtains scalability, leading to practical designs. However, response times of superconductors are often placed in millisecond range, which is not enough for DC power systems.

To achieve a complete and reliable protection against short circuit faults and enhancing DC fault ride-through capability, SFCLs are integrated with DCCBs. Other solutions disclose a simple connection of a Puffer-type mechanical breaker in series with second generation Yttrium barium copper oxide (YBCO) SFCLs in a 400 V DC power system. Other solutions offer s a modified breaker with two improvements: a) connecting a resistor in parallel to the quench resistor and b) connecting a varistor in parallel to the whole breaker. The former connection obtains a current sharing and protects the quench resistor from overheating damages, while the latter connection limits voltage overshoots in the electrical networks. In a more advanced technology, Psome solutions propose a SFCL working together with a hybrid circuit breaker, where an auxiliary branch made of semiconductor switches is paralleled with the series connection of the SFCL and a mechanical breaker. The topology gets rid of commutation passive elements used in other conventional arts and speeds up the reaction time interval to 4.4 milliseconds. Devices having a combination of DCCBs and SFCLs are effective, however, the low-speed operation is a practical issue. To fasten the response time of SFCLs, an active quenching technique may be used. Still, there remains a need for an intelligent protection for DC power systems.

### SUMMARY OF THE INVENTION

This invention relates to DC SSCBs used in DC power systems' protection. In particular, this disclosure presents embodiments to provide an intelligent protection for DC power systems, including both current limiting and current interruption functions.

The invention describes a superconducting solid-state circuit breaker (S³CB) in a DC power system. The DC power system includes a line impedance and a load impedance. The S³CB includes an SSCB that senses a DC current, and isolates current faults based at least in part on the sensed DC current during an occurrence of tripping in the DC power system. The S³CB further includes an intelligent-superconducting fault current limiter (i-SFCL) positioned in series with the SSCB. The i-SFCL limits fault currents associated at least with the sensed DC current in the DC power system.

### BRIEF DESCRIPTION OF THE DRAWINGS

Further advantages of the disclosure will become apparent by reference to the detailed description of preferred embodiments when considered in conjunction with the drawings. In the drawings, identical numbers refer to the same or a similar element.

FIG. 1 illustrates a proposed S³CB in a DC power system including a line impedance, a load impedance, and a DC power supply, in accordance with some embodiments of the present disclosure.

FIG. 2 illustrates a control diagram that includes functions performed by the proposed S³CB, in accordance with some embodiments of the present disclosure.

FIG. 3 illustrates different views of a 3-dimensional (3-D) structure of the proposed i-SFCL, in accordance with some embodiments of the present disclosure.

FIG. 4 illustrates different views of a 3-D structure of the proposed SSCB, in accordance with some embodiments of the present disclosure.

FIG. 5 illustrates different views of the proposed integrated S³CB structure, where an SSCB and an i-SFCL are connected in series, in accordance with some embodiments of the present disclosure.

The drawings supplement the below detailed description.

### DETAILED DESCRIPTION OF THE EMBODIMENTS

This disclosure provides an intelligent protection for DC power systems, which includes both current limiting and current interruption functions in a novel structure, named as superconducting SSCB (S³CB). S³CB includes intelligent superconductor circuits to limit fault currents quickly. Also, an ultrafast SSCB placed in series with superconductor circuits isolates faulty sections in electrical circuits including the DC power systems if fault currents remain on the DC power systems for more than a predefined time interval. To distinguish between current limiting and fault isolation functions, the present disclosure presents a novel control algorithm which implements all the functions presented by the S³CB.

### 2. Technique Approach

### 2.1 Proposed System Structure

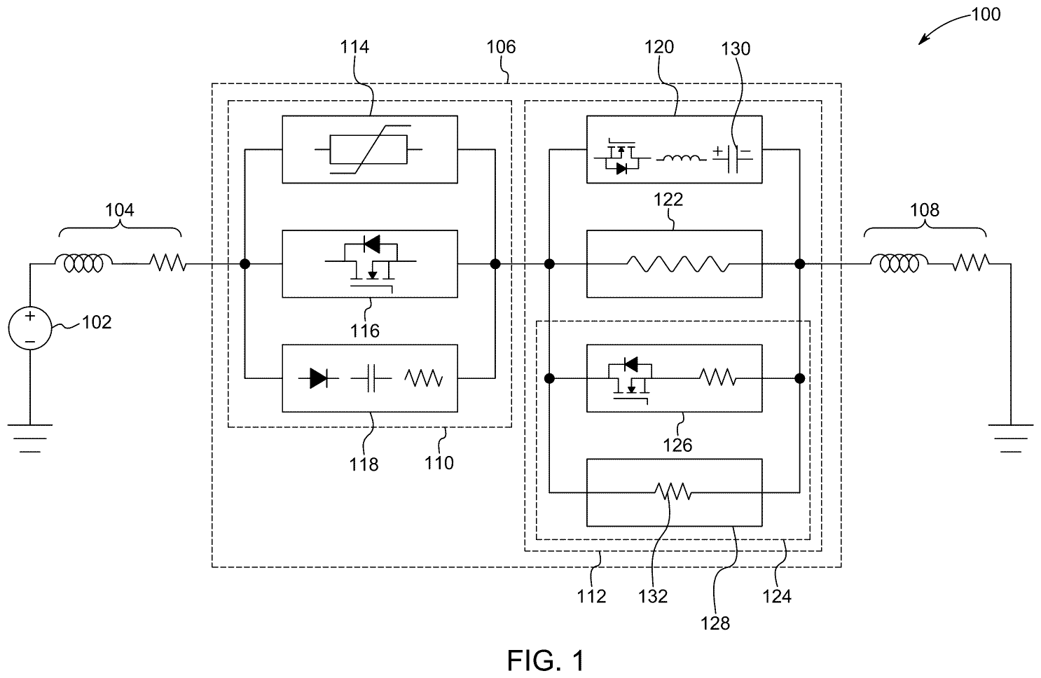

FIG. 1 illustrates a proposed S³CB (106) in a DC power system (100) including a line impedance (104), a load impedance (108), and a DC power supply (102). The proposed S³CB (106) topology may primarily have two parts: the first part being an SSCB (110) that may sense a DC current (i_{dc}), and may isolate current faults based at least in part on the sensed DC current (i_{dc}) during one or more tripping instances in the DC power system (100), and the second part being an intelligent superconducting fault current limiter (112) named as i-SFCL (112), positioned in series with the SSCB (110), and that may limit fault currents associated at least with the sensed DC current (i_{dc}) in the DC power system (100). Further, in some embodiments, the i-SFCL (112) may extend the ride through capability of the DC power system (100). In some embodiments, the ride-through capability of the DC power system (100) may be extended such that the DC power system (100) remains in service during a voltage dip or voltage rise caused by a current fault in the DC power system (100).

In some embodiments, the SSCB (110) may include three branches (114, 116, and 118) of elements connected in parallel with one another: 1) an energy absorption branch (114) including energy absorbing elements that may dissipate inductive energy stored in a line inductance (of the line impedance (104)) in the DC power system (100), 2) a main branch (116) that includes pure solid-state switches and that may act as the normal path for load currents associated with the load impedance (108); and 3) a snubber branch (118) that may slow down a voltage rising rate on the main branch (116) during current interruptions in the DC power system (100). In some embodiments, the energy absorption branch (114) may include metal-oxide-varistors (MOVs) or active MOVs as the energy absorbing elements. In such scenarios, solid-state switches are connected in series with the MOVs or active MOVs to extend the maximum allowable voltage on the SSCB (110) during the OFF state of one or more of the solid-state switches.

Further, in some embodiments, the main branch (116) may include one or more of: metal oxide silicon field effect transistors (MOSFETs), insulated gate bipolar transistors (IGBTs), and integrated gate commutated thyristors (IGCTs), based at least in part on an operating voltage of the DC power system (100) and the maximum fault current aimed to be interrupted in the DC power system (100). Furthermore, in some embodiments, the snubber branch (118) may include one or more of: a pure capacitor, resistor-capacitor (RC), and resistor-capacitor-diode (RCD), based at least in part on voltage and current ratings of the SSCB (110).

In some embodiments, the i-SFCL (112) may include a branch (122) including superconductor elements in the normal path of load currents associated with the load impedance (108). To accelerate a reaction time interval of the i-SFCL (112) during a current limiting process, a quench accelerator (120) may be connected in parallel to the branch (122) including the superconductor elements of the i-SFCL (112). Further, in some embodiments, the quench accelerator (120) may include an active resonant circuit with a precharge capacitor (130) whose injected pulse current is fully controllable in terms of amplitude and duration of the pulse voltage. Besides, to protect the superconductor elements in the branch (122) from localized damages and speed up its recovery time after a current limiting process, a quench protection branch (124) may be provided. In some embodiments, the quench protection branch (124) is connected in parallel to the branch (122) including the superconductor elements of the i-SFCL (112). In some embodiments, the quench protection branch (124) may include a sub-branch (126) including a solid-state switch connected in series with a resistor (for example, a resistor in Ohms or Kilo Ohms) to achieve regulated current sharing in the DC power system (100). Further, the quench protection branch (124) may include another sub-branch (128) including a resistor (132) for speeding up the recovery time of the superconductor elements in the branch (122) after the current limiting process. Further, one or more parasitic inductances in the DC power system (100) may also be considered to determine the gating control of the solid-state switch.

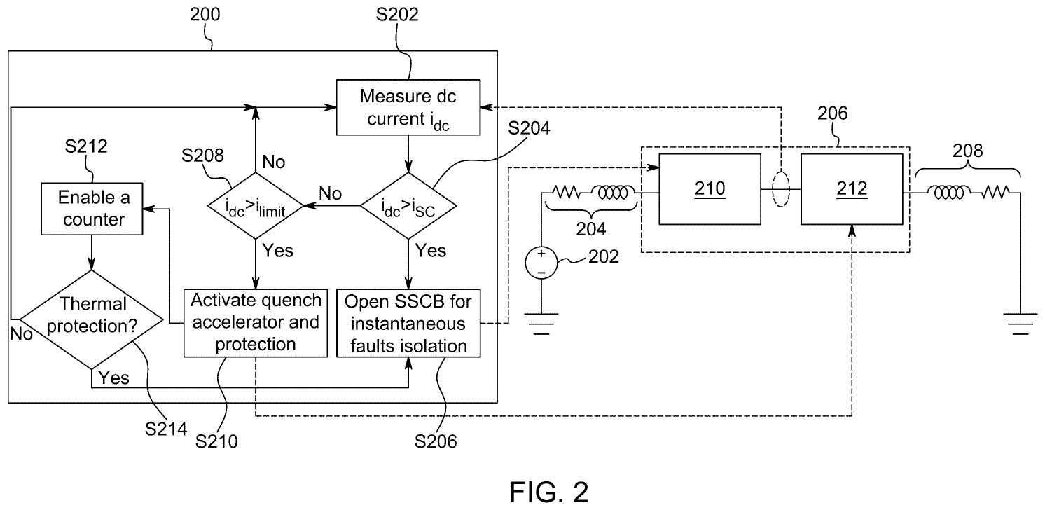

FIG. 2 illustrates a control diagram 200 that includes functions performed by the proposed S³CB (206). FIG. 2 additionally illustrates a DC power supply (202), a line impedance (204), and a load impedance (208).

In some embodiments, the proposed S³CB (206) may include an SSCB (210) and an i-SFCL (212). Further, the S³CB (206), the SSCB (210), the i-SFCL (212), the DC power supply (202), the line impedance (204), and the load impedance (208), are similar in design and functionality to the S³CB (106), the SSCB (110), the i-SFCL (112), the DC power supply (102), the line impedance (104), and the load impedance (108), respectively, as discussed in FIG. 1. Therefore, the detailed description of said entities has not been provided again for the sake of brevity of this disclosure.

In some embodiments, the control diagram (200) may follow three functions: a) short circuit protection, b) superconductors' operation control, and c) DC systems' power converters thermal protection. Further, FIG. 2 will be explained in conjunction with the description of FIG. 1.

In some embodiments, a sensor associated with a DC power system (in which the S³CB (206), the DC power supply (202), the line impedance (204), and the load impedance (208), are included in) or the SSCB (210) may continuously measure a DC current (i_{dc}) at the output of the SSCB (210).

With respect to the functions illustrated in FIG. 2, the control algorithm (200) may be initiated with step S202 in which the sensor (associated with the DC power system) or the SSCB (210) may continuously sense a DC current (i_{dc}) at the output of the SSCB (210). Next, in step S204, the SSCB (210) (or other elements like S³CB (206) may perform this task) may determine if the sensed DC current (i_{dc}) is higher than a short circuit instantaneous threshold value (i_{SC}) associated with the DC power system. If this determination indicates that the sensed DC current (i_{dc}) is higher than the short circuit instantaneous threshold value (i_{SC}), then at step S206, the SSCB (210) may isolate current faults instantaneously and without activating the i-SFCL (212). In some embodiments, the i-SFCL (212) may be in an inactive state during a time interval when the sensed DC current (i_{dc}) is higher than the short circuit instantaneous threshold value (i_{SC}). Further, if the sensed DC current (i_{dc}) is determined to be lower than or equal to the short circuit instantaneous threshold value (i_{SC}), the control algorithm (200) may proceed to step S208. Next, in step S208, the i-SFCL (212) (or another element like S³CB (206)) may determine if the sensed DC current (dc) is higher than a current limiting threshold value (iₗᵢₘᵢₜ) associated with the DC power system. In response to determining that the sensed DC current (i_{dc}) is higher than the current limiting threshold value (iₗᵢₘᵢₜ), a quench accelerator of the i-SFCL (212) may fasten (speed up) a response time of superconductor elements (in the branch of the i-SFCL (212)) in limiting the DC current in the DC power system. In step S212, the i-SFCL (212) (or another element S³CB (206)) may activate a counter associated with the DC power system to check a number of times the quench accelerator of the i-SFCL (212) is activated. Further, in step S214, a quench protection branch of the i-SFCL (212) may protect the superconductor elements of the i-SFCL (212) from localized hotspots and damages that may result due to current spikes in the DC power system. Thus, during current limiting conditions, the proposed S³CB (206) protects power converters in the DC power systems as the DC power systems have low thermal capability when their supply overloads. In the present case, the S³CB (206) obtains a complete protection against short circuit as well as against overload conditions.

### 2.2 Contributions of the Proposed S³CB

Compared with the state-of-the-art technologies, the proposed S³CB features at least following innovations.

Benefiting from the quench accelerator, i-SFCL's reaction time interval is designed to be in the range of hundreds of microseconds, meaning at least one order of magnitude faster than existing technologies. In this case, the S³CB is a promising solution for newly established DC systems.

An active quench accelerator can inject controllable pulse current in terms of amplitude and duration. The features of the controllable pulse current are decided based at least on part on the detected fault current or current limiting conditions. A controllable solid-state switch in the quench accelerating branch is a full-controlled switch, which obtains a full controllability in the DC power system.

Quench protection obtains a fully controllable current sharing branch to protect the quench resistor and fasten the recovery time interval of the i-SFCL. A pulse wide modulation (PWM) is applied on the solid-state switch to regulate the current sharing. The parasitic inductances are also considered to provide a safe operation of the DC power system.

Taking the advantages of i-SFCL, the designed SSCB is very compact: a) as lower line inductance is needed in the DC power system, the energy absorbing branch requires lower energy dissipation capability, b) because of reduction in the peak of fault current, which enables the usage of snubber components with lower current and energy storage capabilities, and c) because SCCB reacts to short circuit faults within microseconds range, meaning an ultrafast operation. This feature helps to isolate the instantaneous short circuit fault to protect solid-state switches from thermal runaway and degradation permanent damages, leading to a high reliability and lifetime.

### 2.3 3-D Design and Conceptual Implementation

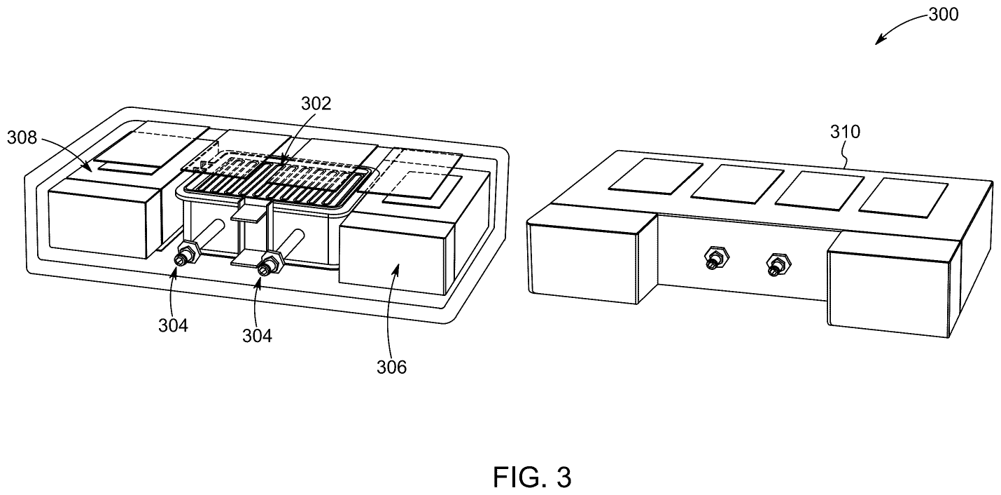

FIG. 3 illustrates different views of a 3-D structure of an i-SFCL (300) which includes three main parts: the first part (302) being a superconductor and a liquid nitrogen coolant place in the center of the i-SFCL (300), where the inlet and outlet tubes (304) for the liquid nitrogen may also be embedded in the topology; the second part (306) being quench protection connected in parallel to the superconductor of the first part (302) to obtain a regulated current sharing function; and the third part (308) being a quench accelerator that is paralleled to the quench resistor to fasten the reaction time interval of the superconductor of the first part (302). The enclosed structure (310) is shown in right side of FIG. 3. Further, the i-SFCL (300) of FIG. 3 is similar in design and functionality to the i-SFCL (112) of FIG. 1 and the i-SFCL (212) of FIG. 2.

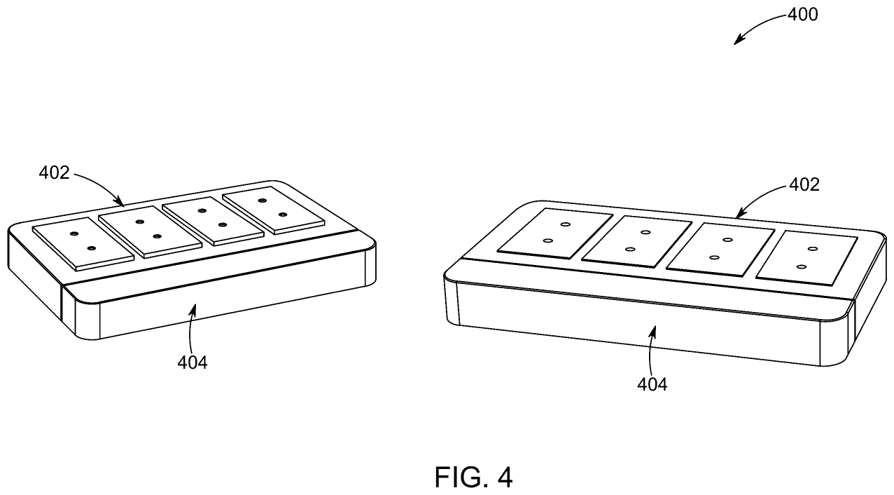

FIG. 4 illustrates different views of a 3-D structure of an SSCB (400) where the main branch (402), the snubber branch (404), and the energy absorbing branch (404) are connected in parallel with one another in a compact structure. Further, the SSCB (400) of FIG. 4 is similar in design and functionality to the SSCB (110) of FIG. 1 and the SSCB (210) of FIG. 2. Furthermore, the main branch (402), the snubber branch (404), and the energy absorbing branch (404) of FIG. 4 are similar in design and functionality to the respective main branch (116), the snubber branch (118), and the energy absorption branch (114) of FIG. 1. Benefiting from the i-SFCL operation, the energy absorbing branch (404) and the snubber branch (404) are compact and tolerate lower electrical voltage and current stresses during DC current interruption. Besides, due to the current limiting function, the main branch (402) undergoes lower peak fault current. This helps to reduces the possibility of thermal damages during short circuit interruption in the DC power systems.

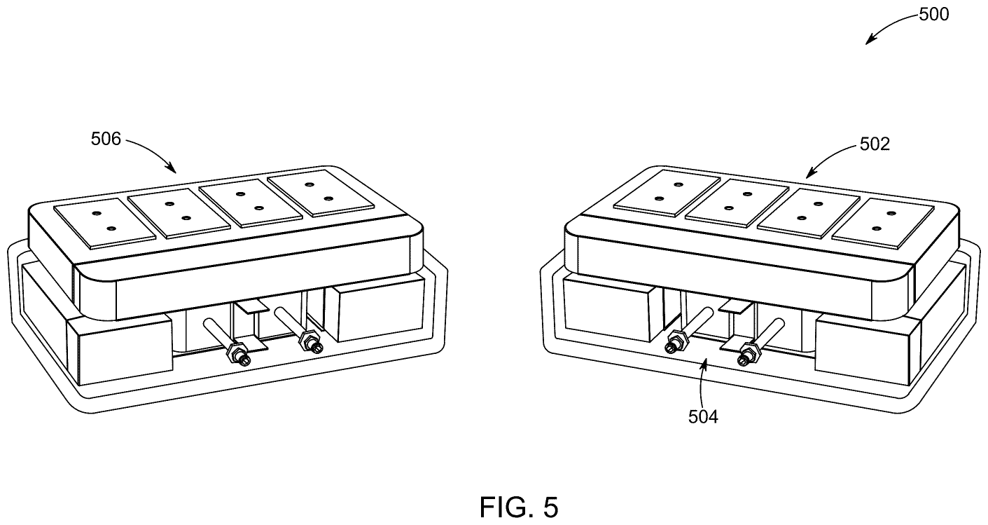

FIG. 5 illustrates different views of integrated S³CB structure (500), where the SSCB (502) and the i-SFCL (504) are connected in series in a complete and compact structure. The S³CB structure (500) of FIG. 5 is similar in design and functionality to the S³CB (106) of FIG. 1 and the S³CB (206) of FIG. 2. Further, the SSCB (502) of FIG. 5 is similar in design and functionality to the SSCB (110) of FIG. 1, the SSCB (210) of FIG. 2, and the SSCB (400) of FIG. 4. Furthermore, the i-SFCL (504) of FIG. 5 is similar in design and functionality to the i-SFCL (112) of FIG. 1, the i-SFCL (212) of FIG. 2, and the i-SFCL (300) of FIG. 3. The i-SFCL (504) often is the first device which reacts to abnormal conditions associated at least with the DC currents. Also, the SSCB (502) actively works with i-SFCL (504) to protect DC power systems in separating faulty sections or disconnecting loads timely and reliably. The presented topology has the advantage of modularity. In this case, multiple SSCB and i-SFCL can be connected in series and parallel to achieve higher voltage and current ratings.

### 3. Conclusion

A novel superconducting solid-state circuit breaker (S³CB) is proposed in this disclosure which takes the full advantage of an ultrafast solid-state circuit breaker (SSCB) and a new intelligent-superconducting fault current limiter (i-SFCL) in a compact structure. The implemented current limiting function reduces the peak of fault currents imposed on the DC power systems and slows down a rising rate of the fault currents to a safe range. The i-SFCL reacts to current faults instantaneously and the superconductors of the i-SFCL are protected from localized damages during fault conditions. The integrated SSCB is compact and efficient, and it isolates the faults within microseconds range, which is highly significant in newly established DC power systems.

### 4. Embodiments

Embodiment 1. A superconducting solid-state circuit breaker (S3CB) in a direct current (DC) power system, wherein the DC power system includes a line impedance and a load impedance, and wherein the S3CB includes:
a solid-state circuit breaker (SSCB) operable to:
sense a DC current; and
isolate current faults based at least in part on the sensed DC current during an occurrence of tripping in the DC power system; and
an intelligent-superconducting fault current limiter (i-SFCL) positioned in series with the SSCB, and operable to limit fault currents associated with the sensed DC current.

Embodiment 2. The S3CB of embodiment 1, wherein the SSCB includes three branches of elements connected in parallel with one another, and wherein the three branches include:
a main branch including solid-state switches, wherein the main branch is operable to function as a path for load currents associated with the load impedance;
a snubber branch operable to slow down a voltage rising rate on the main branch during current interruptions in the DC power system; and
a branch including energy absorbing elements operable to dissipate inductive energy stored in a line inductance of the line impedance in the DC power system.

Embodiment 3. The S3CB of embodiment 2, wherein the main branch includes one or more of: metal oxide silicon field effect transistors (MOSFETs), insulated gate bipolar transistors (IGBTs), and integrated gate commutated thyristors (IGCTs), based at least in part on an operating voltage of the DC power system and the maximum fault current aimed to be interrupted in the DC power system.

Embodiment 4. The S3CB of embodiment 2, wherein the snubber branch includes one or more of: a capacitor, resistor-capacitor (RC), and resistor-capacitor-diode (RCD), based at least in part on voltage and current ratings of the SSCB.

Embodiment 5. The S3CB of embodiment 2, wherein the branch including the energy absorbing elements include metal-oxide-varistors (MOVs) or active MOVs, wherein solid-state switches are connected in series with the MOVs or the active MOVs to extend the maximum allowable voltage on the SSCB during the OFF state of one or more of the solid-state switches.

Embodiment 6. The S3CB of embodiment 1, wherein the i-SFCL includes a branch including superconductor elements in a path of load currents associated with the load impedance.

Embodiment 7. The S3CB of embodiment 6, wherein the i-SFCL further includes a quench accelerator connected in parallel to the branch including the superconductor elements of the i-SFCL.

Embodiment 8. The S3CB of embodiment 7, wherein the quench accelerator includes an active resonant circuit with a precharge capacitor whose injected pulse current is fully controllable.

Embodiment 9. The S3CB of embodiment 6, wherein the i-SFCL further includes a quench protection branch connected in parallel to the branch including the superconductor elements of the i-SFCL, wherein the quench protection branch is operable to protect the superconductor elements in the branch from localized damages and speed up a recovery time of the superconductor elements in the branch after a current limiting process.

Embodiment 10. The S3CB of embodiment 9, wherein the quench protection branch includes:
a sub-branch including a solid-state switch connected in series with a resistor for achieving regulated current sharing in the DC power system; and
another sub-branch including a resistor for speeding up the recovery time of the superconductor elements in the branch after the current limiting process.

Embodiment 11. The S3CB of embodiment 1, wherein the SSCB is operable to isolate the current faults in response to a determination that the sensed DC current is higher than a short circuit instantaneous threshold value associated with the DC power system, and wherein the i-SFCL is in an inactive state during a time interval when the sensed DC current is higher than the short circuit instantaneous threshold value.

Embodiment 12. The S3CB of embodiment 11, wherein the i-SFCL includes a branch including superconductor elements and a quench accelerator, wherein the quench accelerator of the i-SFCL is operable to speed up a response time of the superconductor elements in limiting the sensed DC current in the DC power system, in response to a determination that the sensed DC current is lower than or equal to the short circuit instantaneous threshold value and further in response to a determination that the sensed DC current is higher than a current limiting threshold value associated with the DC power system.

Embodiment 13. The S3CB of embodiment 12, wherein the i-SFCL is further operable to activate a counter associated with the DC power system to check a number of times the quench accelerator is activated.

Embodiment 14. The S³CB of embodiment 12, wherein the i-SFCL further includes a quench protection branch, and wherein the quench protection branch is operable to protect the superconductor elements in the branch from damages that can result due to current spikes in the DC power system, in response to the determination that the sensed DC current is lower than or equal to the short circuit instantaneous threshold value and further in response to the determination that the sensed DC current is higher than the current limiting threshold value.

While the invention has been described with reference to the embodiments above, a person of ordinary skill in the art would understand that various changes or modifications may be made thereto without departing from the scope of the claims.

We claim:

1. A superconducting solid-state circuit breaker (S³CB) in a direct current (DC) power system, wherein the DC power system includes a line impedance and a load impedance, and wherein the S³CB includes:
a solid-state circuit breaker (SSCB) operable to:
sense a DC current; and
isolate current faults based at least in part on the sensed DC current during an occurrence of tripping in the DC power system; and
an intelligent-superconducting fault current limiter (i-SFCL) positioned in series with the SSCB, and operable to limit fault currents associated with the sensed DC current.

2. The S³CB of claim 1, wherein the SSCB includes three branches of elements connected in parallel with one another, and wherein the three branches include:
a main branch including solid-state switches, wherein the main branch is operable to function as a path for load currents associated with the load impedance;
a snubber branch operable to slow down a voltage rising rate on the main branch during current interruptions in the DC power system; and
a branch including energy absorbing elements operable to dissipate inductive energy stored in a line inductance of the line impedance in the DC power system.

3. The S³CB of claim 2, wherein the main branch includes one or more of: metal oxide silicon field effect transistors (MOSFETs), insulated gate bipolar transistors (IGBTs), and integrated gate commutated thyristors (IGCTs), based at least in part on an operating voltage of the DC power system and the maximum fault current aimed to be interrupted in the DC power system.

4. The S³CB of claim 2, wherein the snubber branch includes one or more of: a capacitor, resistor-capacitor (RC), and resistor-capacitor-diode (RCD), based at least in part on voltage and current ratings of the SSCB.

5. The S³CB of claim 2, wherein the branch including the energy absorbing elements include metal-oxide-varistors (MOVs) or active MOVs, wherein solid-state switches are connected in series with the MOVs or the active MOVs to extend the maximum allowable voltage on the SSCB during the OFF state of one or more of the solid-state switches.

6. The S³CB of claim 1, wherein the i-SFCL includes a branch including superconductor elements in a path of load currents associated with the load impedance.

7. The S³CB of claim 6, wherein the i-SFCL further includes a quench accelerator connected in parallel to the branch including the superconductor elements of the i-SFCL.

8. The S³CB of claim 7, wherein the quench accelerator includes an active resonant circuit with a precharge capacitor whose injected pulse current is fully controllable.

9. The S³CB of claim 6, wherein the i-SFCL further includes a quench protection branch connected in parallel to the branch including the superconductor elements of the i-SFCL, wherein the quench protection branch is operable to protect the superconductor elements in the branch from localized damages and speed up a recovery time of the superconductor elements in the branch after a current limiting process.

10. The S³CB of claim 9, wherein the quench protection branch includes:
a sub-branch including a solid-state switch connected in series with a resistor for achieving regulated current sharing in the DC power system; and
another sub-branch including a resistor for speeding up the recovery time of the superconductor elements in the branch after the current limiting process.

11. The S³CB of claim 1, wherein the SSCB is operable to isolate the current faults in response to a determination that the sensed DC current is higher than a short circuit instantaneous threshold value associated with the DC power system, and wherein the i-SFCL is in an inactive state during a time interval when the sensed DC current is higher than the short circuit instantaneous threshold value.

12. The S³CB of claim 11, wherein the i-SFCL includes a branch including superconductor elements and a quench accelerator, wherein the quench accelerator of the i-SFCL is operable to speed up a response time of the superconductor elements in limiting the sensed DC current in the DC power system, in response to a determination that the sensed DC current is lower than or equal to the short circuit instantaneous threshold value and further in response to a determination that the sensed DC current is higher than a current limiting threshold value associated with the DC power system.

13. The S³CB of claim 12, wherein the i-SFCL is further operable to activate a counter associated with the DC power system to check a number of times the quench accelerator is activated.

14. The S³CB of claim 12, wherein the i-SFCL further includes a quench protection branch, and wherein the quench protection branch is operable to protect the superconductor elements in the branch from damages that can result due to current spikes in the DC power system, in response to the determination that the sensed DC current is lower than or equal to the short circuit instantaneous threshold value and further in response to the determination that the sensed DC current is higher than the current limiting threshold value.
